(19) United States
(12) Patent Application Publication
(10) Pub. No.: US 2025/0004388 A1
(43) Pub. Date: Jan. 2, 2025

(54) EXPOSURE APPARATUS, CONTROL METHOD, AND METHOD OF MANUFACTURING ARTICLE

(71) Applicant: CANON KABUSHIKI KAISHA, Tokyo (JP)

(72) Inventor: HIRONOBU FUJISHIMA, Saitama (JP)

(21) Appl. No.: 18/746,356

(22) Filed: Jun. 18, 2024

(30) Foreign Application Priority Data
Jun. 29, 2023 (JP) 2023-107227

(51) Int. Cl. G03F 7/00

(52) U.S. Cl. CPC G03F 7/70775; G03F 7/70425; G03F 7/7055; G03F 7/70666; G03F 7/70725; G03F 7/70875

(57) ABSTRACT

The present invention provides an exposure apparatus for exposing a substrate, the apparatus comprising: a stage configured to move while holding the substrate; a measurement device configured to measure a position of the stage; and a controller configured to control alignment of the substrate based on a position of the mark and interval information, wherein the controller is configured to: at a first timing, cause the measurement device to measure a position of the stage in a predetermined state, as a first position; and at a second timing after the first timing, cause the measurement device to measure a position of the stage in the predetermined state, as a second position, and correct the interval information based on a difference between the first position and the second position.

### BACKGROUND OF THE INVENTION

### Field of the Invention

The present invention relates to an exposure apparatus, a control method, and a method of manufacturing an article.

### Description of the Related Art

Exposure apparatuses that reduction-project and transfer the patterns formed on originals (for example, reticles) onto substrates (for example, wafers) coated with photoresists are widely used in manufacturing processes for semiconductor elements and the like on which micro-patterns are formed. There has been a need to improve pattern resolution in exposure apparatuses and, at the same time, the need to improve the degree of matching (to be referred to as overlay accuracy) between the pattern of an original and the pattern of a substrate has become ever more demanding. Improving the productivity (to be referred to as throughput hereinafter) of apparatuses while satisfying these requirements will be crucial to the appeal of exposure apparatuses.

An exposure apparatus can be provided with an off-axis detection system that detects the positions of a plurality of alignment marks provided on a substrate without going through a projection optical system in order to accurately and quickly perform alignment between an original and a substrate. In a case where alignment is performed between an original and a substrate by using the off-axis detection system, it is necessary to obtain in advance interval information indicating the interval (the so-called baseline) between the optical axis of the off-axis detection system and the optical axis of the projection optical system. Obtaining such interval information in advance makes it possible to perform alignment between an original and a substrate based on the positions of alignment marks obtained by using the off-axis detection system and the baseline.

However, the baseline sometimes varies with time due to, for example, the influences of the deformation of members caused by the heat generated in the exposure apparatus in operation. The variation of the baseline causes a deterioration in overlay accuracy, and hence it is necessary to re-measure or correct the baseline periodically (see, for example, Japanese Patent Laid-Open No. 63-224326).

Recently, exposure apparatuses have been configured to improve the throughput in addition to an improvement in overlay accuracy and have been required to shorten the time required for the correction of the baseline.

### SUMMARY OF THE INVENTION

The present invention provides a technique advantageous in efficiently correcting interval information indicating the interval (baseline) between the optical axis of an off-axis detection system and the optical axis of a projection optical system.

According to one aspect of the present invention, there is provided an exposure apparatus for exposing a substrate through a projection optical system, the apparatus comprising: a stage configured to move while holding the substrate; an image capturing device configured to capture an image of a mark on the substrate without going through the projection optical system; a measurement device configured to measure a position of the stage; and a controller configured to control alignment of the substrate based on a position of the mark and interval information, the position of the mark being obtained by using the image capturing device and the measurement device, and the interval information indicating an interval between an optical axis of the image capturing device and an optical axis of the projection optical system, wherein the controller is configured to: at a first timing at which the interval information is generated, cause the measurement device to measure, as a first position, a position of the stage in a predetermined state in which a reference mark on the stage is arranged within a visual field of the image capturing device; and at a second timing after the first timing, cause the measurement device to measure, as a second position, a position of the stage in the predetermined state, and correct the interval information based on a difference between the first position and the second position.

Further features of the present invention will become apparent from the following description of exemplary embodiments with reference to the attached drawings.

### BRIEF DESCRIPTION OF THE DRAWINGS

FIG. 1 is a schematic view showing an example of the arrangement of an exposure apparatus according to an embodiment of the present invention;

FIG. 2 is a schematic view when a substrate stage is viewed from above (+Z direction);

FIG. 3 is a schematic view when the substrate stage, a projection optical system, and an off-axis detection system are viewed from above (+Z direction); and

FIG. 4 is a flowchart showing the operation of the exposure apparatus according to the embodiment of the present invention.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

### First Embodiment

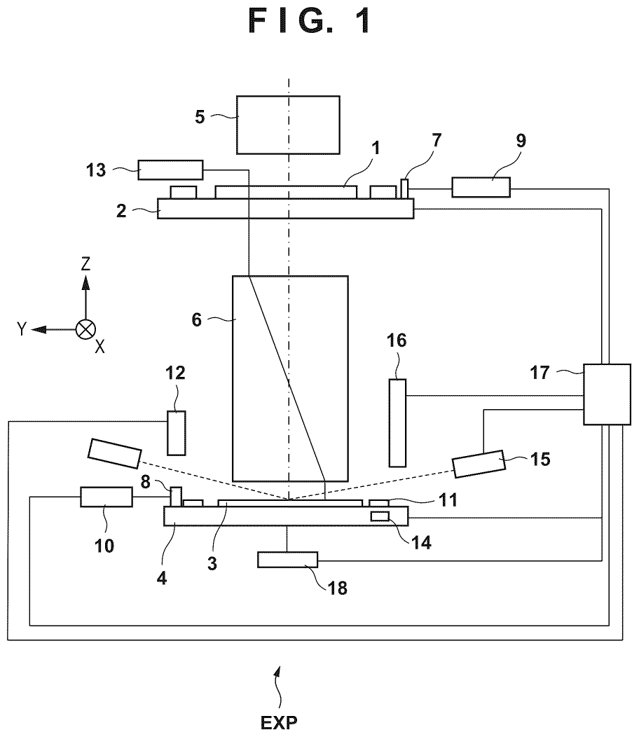

An exposure apparatus EXP according to the first embodiment of the present invention will be described. FIG. 1 is a schematic view showing an example of the arrangement of the exposure apparatus EXP according to the first embodiment. The exposure apparatus EXP can include an original stage 2 that holds an original 1 (for example, a reticle), a substrate stage 4 that holds a substrate 3 (for example, a wafer), and an illumination optical system 5 that illuminates the original 1 held by the original stage 2 with exposure light. The exposure apparatus EXP can include a projection optical system 6 that projects the pattern of the original 1 illuminated with exposure light onto a substrate and forms an image of the pattern on the substrate and a controller 17 that controls the overall operation of the exposure apparatus EXP. In addition, the exposure apparatus EXP can include a substrate driving mechanism 18 that drives the substrate 3 by driving the substrate stage 4 and an original driving mechanism (not shown) that drives the original 1 by driving the original stage 2.

The exposure apparatus EXP can be configured as a scanning exposure apparatus (scanning stepper) that transfers the pattern of the original 1 onto the substrate 3 by synchronously driving the original 1 and the substrate 3 in the scanning direction. Alternatively, the exposure apparatus EXP may be configured as an exposure apparatus (stepper) that transfers the pattern of the original 1 onto the substrate 3 while stopping the original 1 and the substrate 3. In this case, in this embodiment, directions are defined using the XYZ coordinate system in which the direction coinciding with the optical axis of the projection optical system 6 is the Z-axis direction, and the directions orthogonal to the Z-axis direction in a vertical plane are the X-axis direction and the Y-axis direction. In the following description, all the directions parallel to the X-axis defining the XYZ coordinate system are the X-axis directions, all the directions parallel to the Y-axis defining the XYZ coordinate system are the Y-axis directions, and all the directions parallel to the Z-axis defining the XYZ coordinate system are the Z-axis directions. The rotational directions about the X-axis, the Y-axis, and the Z-axis are respectively the 6X, 6Y, and 6Z directions. If the exposure apparatus EXP is configured as a scanning exposure apparatus, the scanning direction of the original 1 and the substrate 3 is the Y-axis direction.

A predetermined illumination region of the original 1 is illuminated by the illumination optical system 5 with exposure light having a uniform illuminance distribution. The illumination optical system 5 can illuminate the original 1 with exposure light emitted from a light source such as a mercury lamp, a KrF excimer laser, or an ArF excimer laser. If i-rays are used as exposure light, a mercury lamp can be used as a light source. In addition, if short-wavelength ultraviolet light is used as exposure light, a KrF excimer laser or an ArF excimer laser can be used as a light source. Alternatively, recently, in order to manufacture a semiconductor element or the like having a micro-pattern, Extreme Ultra Violet Light (EUV light) having a wavelength of several nm to hundred nm is sometimes used as exposure light.

The original stage 2 can be configured to perform two-dimensional movement along a plane perpendicular to the optical axis of the projection optical system 6 (that is, an XY plane) and fine rotation in the 6Z direction while holding the original 1. An original driving mechanism that drives the original stage 2 includes an actuator such as a linear motor and is controlled by the controller 17. A mirror 7 is provided on the original stage 2. A laser interferometer 9 that measures the position of the original stage 2 is provided at a position facing the mirror 7. The laser interferometer 9 measures the X-axis direction position, the Y-axis direction position, and the OZ direction rotational angle of the original stage 2 in real time and provides the measurement results to the controller 17. The controller 17 can position the original 1 held by the original stage 2 by controlling the original driving mechanism based on the measurement results obtained by the laser interferometer 9.

The projection optical system 6 is constituted by a plurality of optical elements and projects the pattern of the original 1 onto the substrate 3 at a predetermined projection magnification 3. In this embodiment, the projection optical system 6 can be configured as a reduction projection system whose projection magnification 3 is less than 1. The projection magnification p can be, for example, ¼ or ⅕.

The substrate stage 4 is configured to be able to move while holding the substrate 3. More specifically, the substrate stage 4 can include a Z stage on which a substrate chuck holding the substrate 3 is mounted and an XY stage that holds the Z stage. The substrate driving mechanism 18 that drives the substrate stage 4 includes an actuator such as a linear motor and is controlled by the controller 17. A mirror 8 is provided on the substrate stage 4. Laser interferometers 10 and 12 that measure the position and the posture of the substrate stage 4 are provided at positions facing the mirror 8. The laser interferometer 10 measures the X-axis direction position, the Y-axis direction position, and the OZ direction rotational angle of the substrate stage 4 in real time and provides the measurement results to the controller 17. The laser interferometer 12 measures the Z-axis direction position and the OX and OY direction rotational angles of the substrate stage 4 in real time and provides the measurement results to the controller 17. The controller 17 can position the substrate 3 held by the substrate stage 4 by controlling the substrate driving mechanism 18 based on the measurement results obtained by the laser interferometers 10 and 12.

In this case, the laser interferometer 10 is configured as a measurement device that measures the position of a reference portion of the substrate stage 4. More specifically, the laser interferometer 10 irradiates the reflecting surface of the mirror 8 of the substrate stage 4 with light and detects the distance to the reflecting surface of the mirror 8 of the substrate stage 4 based on reflected light from the reflecting surface, thereby measuring the position of the reflecting surface as the position of the reference portion of the substrate stage 4. That is, in this embodiment, the reference portion whose position is measured by the laser interferometer 10 is the portion of the substrate stage 4 which is provided with a reflecting surface that reflects light from the laser interferometer 10. In addition, this embodiment has exemplified the laser interferometers 10 and 12 as measurement devices that measure the position of the substrate stage 4 (the position of the reference portion). However, this is not exhaustive, and an encoder may be used. In this case, an encoder scale (grating) can be provided on the substrate stage 4 instead of the mirror 8. The reference portion whose position is measured by the encoder is the portion of the substrate stage 4 which is provided with the encoder scale.

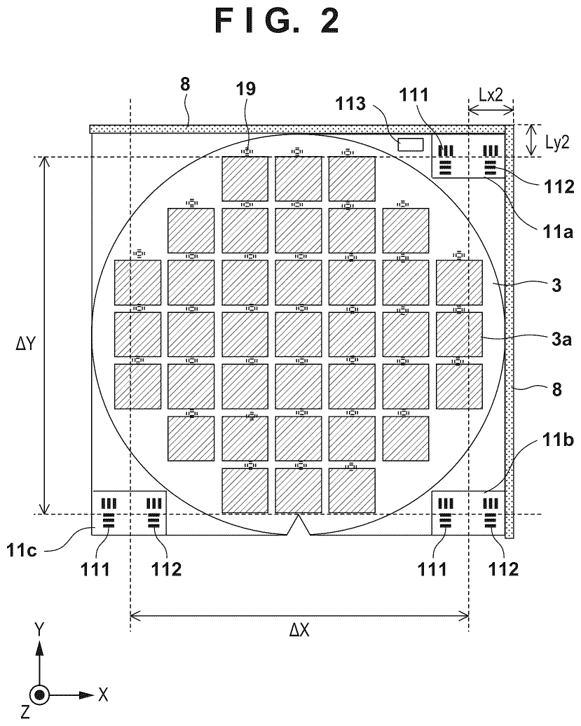

Reference plates 11 are installed at at least two corners of the substrate stage 4 at almost the same level as that of the surface of the substrate 3. FIG. 2 shows a schematic view when the substrate stage 4 is viewed from above (+Z direction). In the case shown in FIG. 2, a plurality of (three) reference plates 11a to 11c are provided on the substrate stage 4. The reference plates 11a to 11c each can include a reference mark 111 that is detected by original position detection systems 13 and 14 and a reference mark 112 that is detected by a position detection system 16. The relative position between the reference mark 111 and the reference mark 112 is known. In addition, the reference mark 111 and the reference mark 112 may have the same shape and may be configured as a reference mark (that is, one reference mark) commonly used by the original position detection systems 13 and 14 and the position detection system 16. In addition, one reference plate 11 may be configured to include a plurality of reference marks 111 and a plurality of reference marks 112.

The original position detection system 13 is arranged near the original stage 2 and detects the reference mark 111 on the substrate stage through the projection optical system 6. In this embodiment, the original position detection system 13 is configured as, for example, an image capturing device (second image capturing device) including a photoelectric conversion element such as a CCD or a CMOS sensor and an image capturing optical system and captures an image of the reference mark 111 on the substrate stage through the projection optical system 6. More specifically, the original position detection system 13 uses the photoelectric conversion element to detect (captures an image of) a reference mark (not shown) on the original stage 2 illuminated by using, for example, a light source of exposure light and the reference mark 111 on the substrate stage 4 and provides the obtained image to the controller 17. The controller 17 detects the relative position between the reference mark on the original stage 2 and the reference mark 111 on the substrate stage 4 based on the image obtained by the original position detection system 13. At this time, the controller 17 adjusts the relative positional relationship between the original stage 2 (the original 1) and the substrate stage 4 (the substrate 3) (in the X, Y, and Z-axis directions) by adjusting the positions/focuses of the reference mark on the original stage 2 and the reference mark 111 on the substrate stage 4. Note that the original position detection system 13 is sometimes called a Through The Lens (TTL) detection system and is sometimes written as the “TTL detection system 13” hereinafter.

In this embodiment, the reference mark on the original stage 2 which is detected by the TTL detection system 13 and the reference mark 111 on the substrate stage 4 are configured as reflection type marks but may be configured as transmission type marks. In this case, the original position detection system 14 can be used instead of the TTL detection system 13. The original position detection system 14 is arranged in the substrate stage 4 below the reference mark 111 and can be configured as an image capturing device (second image capturing device) for detecting (capturing an image of) the transmissive-type reference mark 111. It is possible to detect images (transmitted light) transmitted through the reference mark on the original stage 2 and the reference mark 111 on the substrate stage 4 by using the original position detection system 14 while driving the substrate stage 4 in the X-axis direction, the Y-axis direction, and the Z-axis direction. This enables the controller 17 to detect the relative position between the reference mark on the original stage 2 and the reference mark 111 on the substrate stage 4 based on the detection result obtained by the original position detection system 14. At this time, the controller 17 can also adjust the relative positional relationship (in the X-, Y-, and Z-axis directions) between the original stage 2 (the original 1) and the substrate stage 4 (the substrate 3) by adjusting the positions/focuses of the reference mark on the original stage 2 and the reference mark 111 on the substrate stage 4.

The position detection system 16 is arranged on a side of the projection optical system 6 and detects a mark on the substrate stage (for example, an alignment mark 19 on the substrate 3 or the reference mark 112 on the reference plate 11) without going through the projection optical system 6. In this embodiment, the position detection system 16 is configured as an image capturing device (first image capturing device) including a photoelectric conversion element such as a CCD or a CMOS sensor and an image capturing optical system and captures an image of the reference mark 112 on the substrate stage without going through the projection optical system 6. More specifically, the position detection system 16 can include a projection system that projects detection light onto a mark on the substrate stage 4 and a light-receiving system that receives reflected light from the mark. The position detection system 16 is connected to the controller 17 and provides the detection result obtained by the position detection system 16 to the controller 17. The controller 17 can perform positioning with respect to the X-axis direction, the Y-axis direction, and the OZ-axis direction of the substrate 3 held by the substrate stage 4 by driving the substrate stage 4 in the X-axis direction, the Y-axis direction, and the OZ-axis direction based on the detection result obtained by the position detection system 16. Note that the position detection system 16 is sometimes called an off-axis detection system and is sometimes written as the “off-axis detection system 16”.

A focus detection system 15 can include a light-emitting system that emits detection light onto the surface of the substrate 3 by oblique incidence and a light-receiving system that receives reflected light from the substrate 3. The detection result obtained by the focus detection system 15 can be provided to the controller 17. The controller 17 adjusts the position (focus position) and the inclination angle of the substrate 3 in the Z-axis direction which is held by the substrate stage 4 by causing the substrate driving mechanism 18 to drive the substrate stage 4 (Z stage) based on the detection result obtained by the focus detection system 15.

The controller 17 is configured by a processor such as a Central Processing Unit (CPU) and a computer (information processing apparatus) having a storage device such as a memory and controls exposure processing on the substrate 3 by controlling each device of the exposure apparatus EXP. The exposure processing may be understood as the processing of transferring the pattern of the original 1 onto the substrate and may also be understood as including alignment between the original 1 and the substrate 3. As shown in FIG. 2, the exposure processing can be sequentially performed with respect to each of a plurality of shot regions 3a arranged (set) on the substrate 3. In addition, the controller 17 is implemented by, for example, a Programmable Logic Device (PLD) such as a Field Programmable Gate Array (FPGA), an Application Specific Integrated Circuit (ASIC), a general-purpose or dedicated computer incorporating programs, or a combination of all or some of these components.

In this case, the position information of the substrate 3 (the shot region 3a) which is obtained by detecting the alignment mark 19 on the substrate 3 using the position detection system 16 is information based on the optical axis of the position detection system 16. Accordingly, this position information needs to be converted into information based on the optical axis of the projection optical system 6. Such conversion uses interval information indicating the interval (the so-called baseline) between the optical axis of the position detection system 16 and the optical axis of the projection optical system 6. In the following description, this interval is sometimes written as the “baseline”, and the interval information is sometimes written as “baseline information”.

Baseline information can be generated based on the difference between the position of the reference mark on the substrate stage 4 which is measured using the position detection system 16 (first image capturing device) and the position of the reference mark on the substrate stage 4 which is measured using the TTL detection system 13 (second image capturing device). More specifically, the controller 17 causes the laser interferometer 10 (measurement device) to measure the position of the substrate stage 4 while the reference mark 112 on the substrate stage 4 is arranged at a predetermined position (for example, the visual field center) in the visual field (field of view) of the position detection system 16. The controller 17 can also cause the laser interferometer 10 (measurement device) to measure the position of the substrate stage 4 while the reference mark 111 on the substrate stage 4 is arranged at a predetermined position (for example, the visual field center) in the visual field of the TTL detection system 13. This enables the controller 17 to generate baseline information by setting the difference between the measurement result obtained using the position detection system 16 and the measurement result obtained using the TTL detection system 13 as a baseline.

When the laser interferometer 10 measures the position of the substrate stage 4, shortening an optical path between the laser interferometer 10 and the mirror 8 as much as possible can reduce the influence of fluctuation in air refractive index in the optical path. That is, the position of the substrate stage 4 can be accurately measured. Accordingly, in generating baseline information, it is preferable to use the reference plate 11c, of the plurality of reference plates 11a to 11c (reference marks) on the substrate stage 4, which is farthest from the reflecting surface of the mirror 8 as a reference portion whose position is measured by the laser interferometer 10. Using the reference plate 11c can shorten the optical path of the laser interferometer 10 while reference marks are arranged in the visual fields of the position detection system 16 and the TTL detection system 13 as compared with using the other reference plates 11a and 11b. In this embodiment, although the off-axis detection system 16 and the TTL detection system 13 respectively detect the different reference marks 111 and 112, this is not exhaustive. These systems may detect same reference marks.

The exposure apparatus EXP according to this embodiment is provided with a temperature detector 113 that detects the temperature of the substrate stage 4. The temperature detector 113 can be arranged near the reference plate 11a, of the plurality of reference plates 11a to 11c, which is nearest to the reflecting surface of the mirror 8.

The operation of the exposure apparatus EXP described above will be described below. In general, a predetermined number of substrates 3 loaded into the exposure apparatus EXP constitute one unit of processing in consideration of portability and the securement of traceability within a semiconductor plant. Such unit of processing is constituted by a plurality of substrates 3 to be subjected to similar exposure processing and can be called a “lot”. Normally, 25 substrates 3 often constitute one lot due to restriction from the maximum number of substrates 3 in the substrate conveying container. All the substrates 3 belonging to this lot are subjected to exposure processing using the same original 1.

When a lot is loaded into the exposure apparatus EXP, two cases are assumed, including replacing the original 1 and not replacing the original 1. In either case, it is necessary to complete alignment between the original 1 and the substrate 3 before the start of exposure processing for the first substrate 3. That is, processing of measuring the focus position of the substrate 3 using the focus detection system 15 and measuring the position of the alignment mark 19 on the substrate 3 using the off-axis detection system 16 is executed before the alignment. In the first alignment, first of all, the reference mark 111 on the substrate stage 4 is set within the visual field of the TTL detection system 13 (for example, captured at the visual field center). The laser interferometer 10 measures the X-axis direction position and the Y-axis direction position of the substrate stage 4 in real time at this time and provides (transmits) the measurement results to the controller 17. The reference mark 112 on the substrate stage 4 is set within the visual field of the off-axis detection system 16 (for example, captured at the visual field center). The laser interferometer 10 measures the X-axis direction position and the Y-axis direction position of the substrate stage 4 in real time at this time and provides (transmits) the measurement results to the controller 17. The controller 17 calculates the difference between these two measurement results (that is, the positions (coordinates) of the substrate stage 4 and generates baseline information using the difference as a baseline. In the following description, the generation of baseline information using both the off-axis detection system 16 an the TTL detection system 13 is sometimes simply written as “the generation of baseline information”.

Once the first alignment including the generation of baseline information for the substrate 3 at the head of the lot is completed, the head substrate 3 of the lot is subjected to exposure processing, and at the same time, the remaining substrates 3 of the lot are sequentially subjected to exposure processing. In this process, exposure light and energy for driving the stage are partly converted into heat, resulting in changes in the temperatures in the inner space of the exposure apparatus EXP and constituent members. The inside of the exposure apparatus EXP is constituted by members whose variation in dimension due to heat is minimum and is designed in consideration of temperature adjustment using an air cooling mechanism or the like. In practice, however, a slight temperature change can cause variation in baseline. After the baseline varies, keeping using the baseline information generated in the first alignment can cause a deterioration in overlay accuracy.

The detection of a reference mark on the substrate stage 4 by the TTL detection system 13 through the projection optical system 6 requires a long time as compared with the detection of a reference mark on the substrate stage 4 by the off-axis detection system 16. Accordingly, regenerating or correcting baseline information using the TTL detection system 13 will decrease the throughput (that is, the productivity of apparatuses). For this reason, it is preferable to avoid the use of the TTL detection system 13 except for the head substrate 3 of the lot.

Accordingly, in this embodiment, baseline information is corrected by using only the off-axis detection system 16. More specifically, the controller 17 causes the laser interferometer 10 to measure, as the first position, the position of the substrate stage 4 at the first timing at which baseline information is generated, in a predetermined state in which the reference mark 112 is arranged within the visual field of the off-axis detection system 16. The first timing can be, for example, a timing at which the first alignment for the generation of baseline information is performed with respect to the head substrate 3 of the lot. The predetermined state can be a state in which the reference mark 112 is arranged at a predetermined position (for example, the visual field center) within the visual field of the off-axis detection system 16. The controller 17 then causes the laser interferometer 10 to measure the position of the substrate stage 4 in the predetermined state as the second position at the second timing after the first timing. The controller 17 then corrects the baseline information based on the difference between the first position and the second position. Note that in the following description, the correction of baseline information using only the position detection system 16 is sometimes simply written as the “correction of baseline information”.

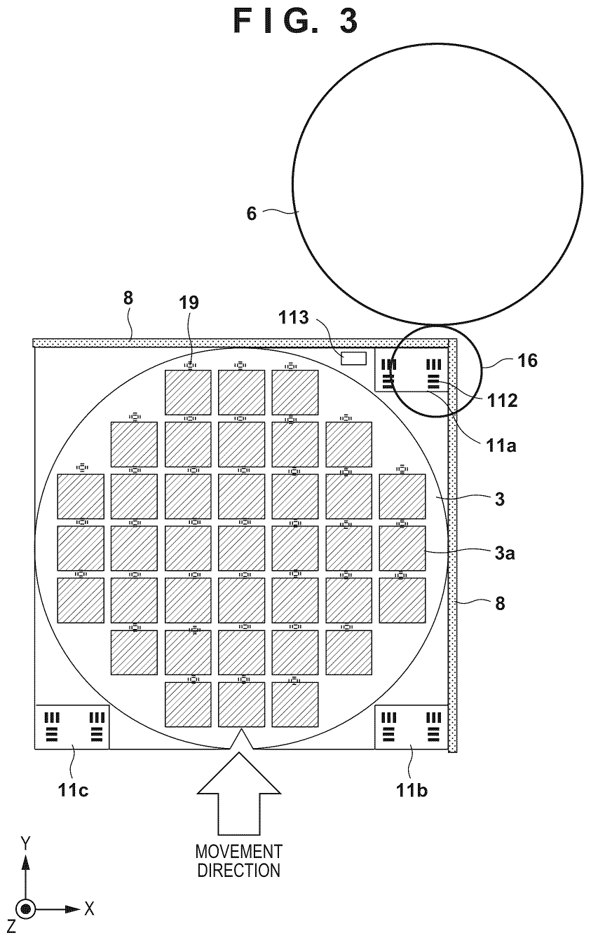

The correction of baseline information uses the reference mark 112 nearer to the reference portion (the reflecting surface of the mirror 8) of the substrate stage 4 than the reference mark 112 (second reference mark) on the reference plate 11c used for the generation of baseline information. In this embodiment, of the plurality of reference plates 11a to 11c on the substrate stage 4, the reference mark 112 on the reference plate 11a nearest to the mirror 8 is used for the correction of baseline information. Of the reference plates 11a to 11c, the reference plate 11a may be understood as a reference plate nearest to the off-axis detection system 16 in a state in which the substrate stage 4 is arranged in a substrate loading place. The substrate loading place can be defined as a place where the substrate stage 4 is arranged when the substrate 3 is loaded (supplied) onto the substrate stage 4 by the substrate conveying mechanism (not shown). As shown in FIG. 3, selecting the reference plate 11a in this manner can arrange the reference plate 11a below the off-axis detection system 16 in the process of moving the substrate stage 4 from the substrate loading place to below the projection optical system 6. That is, it is possible to arrange the reference mark on the reference plate 11a within the visual field of the off-axis detection system 16 without greatly changing the route of the substrate stage 4 from the substrate loading place to below the projection optical system 6. This is advantageous in throughput. FIG. 3 is a schematic view when the substrate stage 4, the projection optical system 6, and the off-axis detection system 16 are viewed from above (+Z direction).

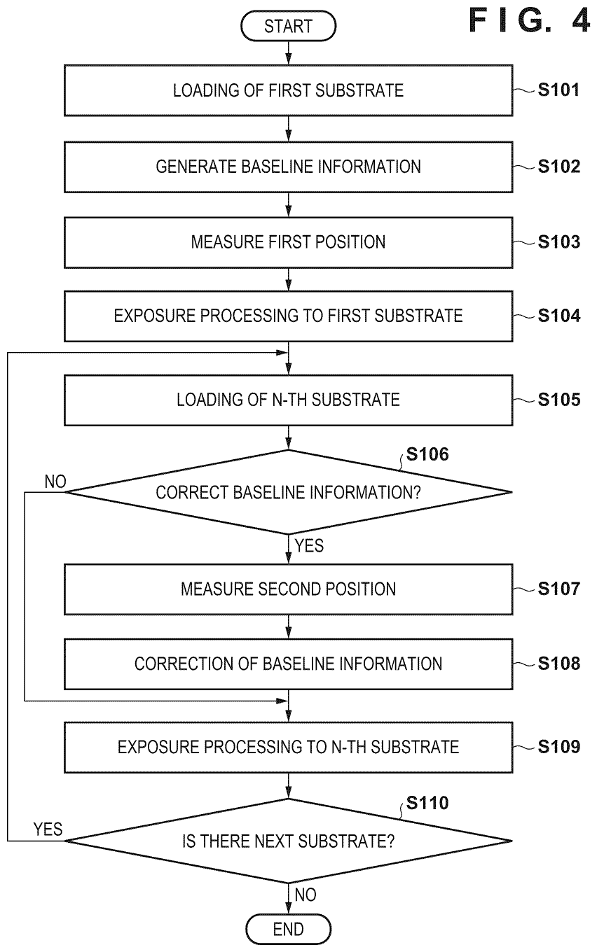

FIG. 4 is a flowchart showing the operation of the exposure apparatus EXP according to this embodiment. The flowchart in FIG. 4 exemplifies the operation of the exposure apparatus EXP with respect to one lot having a plurality of (for example, 25) substrates 3. If there are a plurality of lots, the flowchart in FIG. 4 can be repeatedly executed. The flowchart in FIG. 4 can be executed by the controller 17. The flowchart in FIG. 4 may be understood as a flowchart showing a control method for the exposure apparatus EXP.

Steps S101 to S104 are steps for performing exposure processing for the first (head) substrate 3 of the lot.

In step S101, the controller 17 loads the first (head) substrate 3 of the lot onto the substrate stage 4 using the substrate conveying mechanism (not shown). The substrate 3 can be loaded onto the substrate stage 4 while the substrate stage 4 is arranged in the substrate loading place. In step S102, the controller 17 generates baseline information. Baseline information is generated by detecting the reference mark 111 on the reference plate 11c by using both the off-axis detection system 16 and the TTL detection system 13. As described above, the reference plate 11c can be a reference plate farthest from the reflecting surface of the mirror 8 as a reference portion whose position is measured by the laser interferometer 10 among the plurality of reference plates 11a to 11c on the substrate stage 4. The details of the generation of baseline information are the same as those described above, and hence a description of them will be omitted here.

This embodiment exemplifies the case where baseline information is generated for each lot. However, this is not exhaustive, and baseline information may be generated for a lot satisfying a predetermined condition. The predetermined condition includes a condition that the target lot is the first lot after the original 1 is replaced and a condition that the target lot is the first lot after the maintenance of the exposure apparatus EXP.

In step S103, the controller 17 causes the laser interferometer 10 to measure, as the first position, the position of the substrate stage 4 in a predetermined state in which the reference mark 112 on the reference plate 11a is arranged within the visual field of the off-axis detection system 16. As described above, the reference plate 11a can be a reference plate nearest to the reflecting surface of the mirror 8 as a reference portion whose position is measured by the laser interferometer 10 among the plurality of reference plates 11a to 11c on the substrate stage 4. Step S103 may be understood as a step executed at the first timing at which baseline information is generated. A storage device stores the position (first position) of the substrate stage 4 measured in step S103.

In step S104, the controller 17 performs exposure processing for each of the plurality of shot regions 3a on the first substrate 3. As described above, the exposure processing is the processing of transferring the pattern of the original 1 onto a substrate. The exposure processing can include the processing of obtaining the position information of the substrate 3 (the shot region 3a) by detecting the alignment mark 19 on the substrate 3 using the off-axis detection system 16 and performing alignment between the original 1 and the substrate 3 based on the position information of the substrate 3 and the baseline information.

Steps S105 to S110 are steps for performing exposure processing for the second and subsequent substrates 3 of the lot.

In step S105, the controller 17 causes a substrate conveying mechanism (not shown) to unload (recover) the substrate 3 having undergone exposure processing from on the substrate stage 4 and, at the same time, load the nth substrate 3 subjected to next exposure processing onto the substrate stage 4. In this case, “n” represents the ordinal number of the second or subsequent substrate 3 of the lot, and an integer of two or more is input. Unloading of the substrate 3 from on the substrate stage 4 and loading of the substrate 3 onto the substrate stage 4 can be performed while the substrate stage 4 is arranged in the substrate loading place.

In step S106, the controller 17 determines whether to correct the baseline information. If the controller 17 determines that the baseline information is to be corrected, the process advances to step S107. If the controller 17 determines that the baseline information is not to be corrected, the process advances to step S109.

A determination criterion for determining whether to correct baseline information is given by, for example, collating the operational status of the exposure apparatus EXP and feedback from an overlay inspector and estimating the timing at which the variation amount of a baseline exceeds an allowable range. It may be configured to input, to the exposure apparatus EXP in advance, the specific substrate 3 of the lot for which baseline information is corrected at the time of exposure processing, that is, the ordinal number of the substrate 3 for which baseline information is corrected at the time of exposure processing. Alternatively, the controller 17 may perform such determination using an algorithm or learning mechanism incorporated in the controller 17 so as to satisfy both requirements for throughput and overlay accuracy based on feedback from the overlay inspector or information from various types of sensors (for example, the temperature detector 113) of the exposure apparatus. For example, the ordinal number of the substrate 3 whose overlay accuracy exceeds an allowable range can be determined as the ordinal number of the substrate 3 to be subjected to the correction of baseline information at the time of exposure processing based on the result of overlay accuracy inspection with respect to the plurality of substrates 3 of the previous lot. The ordinal number of a substrate to be subjected to the correction of baseline information at the time of exposure processing may be sequentially updated. Alternatively, if the temperature of the substrate stage 4 which is measured by the temperature detector 113 exceeds a threshold, it may be determined that the correction of baseline information may be executed.

In step S107, the controller 17 causes the laser interferometer 10 to measure, as the second position, the position of the substrate stage 4 in a predetermined state in which the reference mark 112 on the reference plate 11a is arranged within the visual field of the off-axis detection system 16. The reference plate 11a is the reference plate used in step S103 described above. Step S107 may be understood as a step to be executed at the second timing after the first timing at which baseline information is generated. The storage device stores the position (second position) of the substrate stage 4 which is measured in step S107.

In step S107, the position of the reference mark 112 on the reference plate 11a is quickly measured by using only the off-axis detection system 16 without using the projection optical system 6 and the TTL detection system 13. In addition, measurement in step S107 uses the reference plate 11a. As described above with reference to FIG. 3, this makes it possible to arrange the reference plate 11a below the off-axis detection system 16 without greatly changing the route of the substrate stage 4 from the substrate loading place to below the projection optical system 6, thereby providing an advantage in terms of throughput.

In step S108, the controller 17 calculates the difference between the first position obtained in step S103 and the second position obtained in step S107 and corrects the baseline information based on the difference. Letting the first position be “OAS(0)” and the second position be “OAS(t)”, a correction value ΔBL for correcting the baseline information is represented by “ΔBL=OAS(0)−OAS(t)”. In consideration of X-axis direction components and Y-axis direction components, correction values ΔBLx and ΔBLy for correcting the baseline information can be represented by equations (1) given below:

$$Δ BLx = OASx ( 0 ) - OASx ( t ) \\ Δ BLy = OASy ( 0 ) - OASy ( t ) \qquad ( 1 )$$

When the position of the reference mark 112 is measured at the first timing of the generation of baseline information (step S103) and the second timing after the first timing (step S107), different measurement results can be obtained. The reason why the measurement results of the position of the reference mark 112 at the first timing and the second timing differ from each other may be that, for example, the baseline has varied due to the influence of heat generated during the operation of the exposure apparatus EXP. That is, the difference between the first timing and the second timing regarding the measurement results of the position of the reference mark 112 can be understood as the variation amount of the baseline. Accordingly, correcting the baseline information based on the difference makes it possible to accurately perform alignment between the original 1 and the substrate 3 to be subjected to exposure processing thereafter and set the overlay accuracy within the allowable range. In addition, correcting the baseline information in a similar manner with respect to other lots can improve the overlay accuracy while minimizing a deterioration in throughput by avoiding the generation of baseline information using the projection optical system 6 and the TTL detection system 13.

In step S109, the controller 17 performs exposure processing for each of the plurality of shot regions 3a on the nth substrate 3. In step S110, the controller 17 determines whether the lot includes the substrate 3 to be subjected to exposure processing next (to be sometimes referred to as the next substrate 3 hereinafter), that is, whether the lot includes any substrate 3 that has not been subjected to exposure processing. If there is the next substrate 3, the process returns to step S105 to execute steps S105 to S109 with respect to the next substrate 3. If there is not the next substrate 3, the substrate conveying mechanism (not shown) unloads the substrate 3 having undergone exposure processing from on the substrate stage 4, thereby terminating the flowchart in FIG. 4.

As described above, the exposure apparatus EXP according to this embodiment corrects the baseline information using only the off-axis detection system 16. This makes it possible to improve the overlay accuracy and provides an advantage in terms of throughput as compared with the case where the baseline information is regenerated or corrected by using the TTL detection system 13.

### Second Embodiment

The second embodiment according to the present invention will be described. The first embodiment has exemplified the case where the baseline information is corrected based on the difference between the first position obtained at the first timing (step S103) and the second position obtained at the second timing (step S107). The second embodiment will exemplify a case where baseline information is further corrected based on the difference between the first timing and the second timing concerning the distance between a reference portion (the reflecting surface of a mirror 8) of a substrate stage 4 and a reference mark 112 on a reference plate 11a. Note that this embodiment basically inherits the first embodiment and can comply with the first embodiment except for the matters described below.

Another advantage can be seen in using a reference plate 11a, of a plurality of reference plates 11a to 11c on the substrate stage 4, which is nearest to the mirror 8 in the correction of baseline information using only an off-axis detection system 16. In order to identify the difference between the first position obtained at the first timing (step S103) and the second position obtained at the second timing (step S107) as the variation amount of the baseline between the first timing and the second timing as described above, the following premise is required. That is, it is possible to neglect the thermal deformation (thermal expansion/contraction) of the substrate stage 4 itself with changes in the temperature of the substrate stage 4 itself and surrounding atmospheric temperature. In examining the validity of this premise, it is important to consider the placement of the mirror 8 described with reference to FIG. 2. Laser interferometers 10 and 12 for measuring the position of the substrate stage 4 exist at positions facing the mirror 8. The reference plate 11a used for the correction of baseline information is arranged such that the distance from the mirror 8 extending in the X-axis direction and the Y-axis direction is shorter than the distances between the mirror 8 and the remaining reference plates 11b and 11c.

In general, a thermal expansion coefficient describing the thermal deformation amount of a given substance per unit temperature change is a ratio represented by a dimensionless quantity ppm. An actual thermal deformation amount increases with an increase in distance from a reference point. A point serving as a reference for this thermal deformation amount corresponds to the reflecting surface (surface) of the mirror 8 on the substrate stage 4. Accordingly, the amount of variation in the position of the reference mark 112 on the reference plate 11a arranged near the reflecting surface of the mirror 8 due to the thermal deformation of the substrate stage 4 is relatively small.

In practice, however, since the distance between the reflecting surface of the mirror 8 and the reference mark 112 on the reference plate 11a is not zero, the change amount of the distance due to the temperature (thermal deformation) of the substrate stage 4 is not zero. Consequently, even if baseline information is corrected as in the first embodiment, a correction residual error occurs in accordance with the change amount of the distance due to the temperature of the substrate stage 4. Accordingly, in this embodiment, a controller 17 obtains the difference (distance difference) between the first timing and the second timing concerning the distance between the reflecting surface of the mirror 8 and the reference mark 112 on the reference plate 11a based on the difference between the temperatures of the substrate stage 4 at the first timing and the second timing. The baseline information is further corrected based on the difference. The difference between the temperatures of the substrate stage 4 at the first timing and the second timing can be obtained by using a temperature detector 113 provided on the substrate stage 4. Note that the distance between the reflecting surface of the mirror 8 and the reference mark 112 is sometimes written as the “mark distance”.

More specifically, in step S108, the controller 17 can obtain the correction value ΔBL for correcting the baseline information by “ΔBL=OAS(0)−{OAS(t)−ΔWS”. In this equation, “OAS(0)” represents the first position, “OAS(t)” represents the second position, and “ΔWS” represents the change amount of the mark distance between the first timing and the second timing concerning the reference mark 112 on the reference plate 11a. In addition, in consideration of X-axis direction components and Y-axis direction components, correction values ΔBLx and ΔBLy for correcting the baseline information can be represented by equations (2):

$$Δ BLx = OASx ( 0 ) - \{ OASx ( t ) - Δ WSx \} \\ Δ BLy = OASy ( 0 ) - \{ OASy ( t ) - Δ WSy \} \qquad ( 2 )$$

A method of obtaining change amounts ΔWSx and ΔWSy of the mark distance will be described here. The change amounts ΔWSx and ΔWSy of the mark distance can be calculated based on a thermal expansion coefficient (ax, ay) of the substrate stage 4. The thermal expansion coefficient (ax, ay) may be understood as a coefficient for converting the change amount of the temperature of the substrate stage 4 into the change amounts ΔWSx and ΔWSy of the mark distance. In addition, the thermal expansion coefficient (ax, ay) can be obtained in advance by using the reference plates 11a to 11c (the reference marks 112) respectively provided on a plurality of corners of the substrate stage 4 and the temperature detector 113 that detects the temperature of the substrate stage 4. For example, the thermal expansion coefficient (ax, ay) can be obtained by a simulated operation in an adjustment step performed in advance for the production of an exposure apparatus EXP.

More specifically, as shown in FIG. 2, the thermal expansion coefficient (αx, αy) can be obtained by using the reference plates 11a (upper right in FIG. 2) and 11c (lower left in FIG. 2), of the plurality of reference plates 11a to 11c on the substrate stage 4, which are located at diagonal positions. Assume that the reference plate 11a and the reference plate 11c differ in design coordinates by (ΔX, ΔY).

First of all, in an initial state, the position of the reference mark 112 on the reference plate 11c (lower left in FIG. 2) is measured by using the off-axis detection system 16, and the obtained measured value is represented by (x1, y1). The measurement of the position of the reference mark 112 with the off-axis detection system 16 is performed by measuring the position of the substrate stage 4 with the laser interferometer 10 in a predetermined state in which the reference mark is arranged within the visual field of the off-axis detection system 16. Likewise, the position of the reference mark 112 on the reference plate 11a (upper right in FIG. 2) is measured by using the off-axis detection system 16, and the obtained measured value is represented by (x2, y2). These measured values can vary with a change in the temperature of the substrate stage 4 which reflects the operation state of the exposure apparatus EXP.

Measurement similar to that in the initial state is performed in a state in which the read value of the temperature detector 113 (that is, the temperature of the substrate stage 4) has changed due to the operation of the exposure apparatus EXP. That is, the position of the reference mark 112 on the reference plate 11c (lower left in FIG. 2) is measured by using the off-axis detection system 16, and the obtained measured value is represented by (x1′, y1′). Likewise, the position of the reference mark 112 on the reference plate 11a (upper right in FIG. 2) is measured by using the off-axis detection system 16, and the obtained measured value is represented by (x2′, y2′). This makes it possible to obtain the thermal expansion coefficient (αx, αy) of the substrate stage 4 by equations (3) given below when the change amount of the temperature of the substrate stage 4 relative to that in the initial state is represented by ΔTa. The thermal expansion coefficient (αx, αy) obtained in advance in this manner can be stored in the storage device.

$$α x = \{ ( x {1}^{′} - x 1 ) - ( x {2}^{′} - x 2 ) \} / ( Δ X \cdot Δ Ta ) \\ α y = \{ ( y {1}^{′} - y 1 ) - ( y {2}^{′} - y 2 ) \} / ( Δ Y \cdot Δ Ta ) \qquad ( 3 )$$

For illustrative purposes, (Lx2, Ly2) represents a design mark distance concerning the reference mark 112 on the reference plate 11a (upper right in FIG. 2), and ΔTb represents the temperature difference of the substrate stage 4 between the first timing and the second timing. In this case, the controller 17 can calculate the change amounts ΔWSx and ΔWSy of the mark distance by equations (4) given below. Note that the temperature difference ΔTb of the substrate stage 4 can be obtained by using the temperature detector 113. That is, it is possible to obtain, as the temperature difference ΔTb, the difference between the temperature of the substrate stage 4 which is detected by the temperature detector 113 at the first timing and the temperature of the substrate stage 4 which is detected by the temperature detector 113 at the second timing.

$$Δ WSx = α x \cdot Δ Tb \cdot Lx 2 \\ Δ WSy = α y \cdot Δ Tb \cdot Ly 2 \qquad ( 4 )$$

In this manner, it is possible to obtain the change amounts ΔWSx and ΔWSy of the mark distance due to the temperature (thermal deformation) of the substrate stage 4 by multiplying the thermal expansion coefficient (αx, αy) of the substrate stage 4 and the design mark distance (Lx2, Ly2). As indicated by equations (2) described above, the overlay accuracy can be further improved by further correcting the baseline information with the change amounts ΔWSx and ΔWSy of the mark distance.

### Embodiment of Method of Manufacturing Article

A method of manufacturing an article according to an embodiment of the present invention is suitable for manufacturing an article, for example, a microdevice such as a semiconductor device or an element having a microstructure. The method of manufacturing the article according to this embodiment includes an exposure step of exposing a substrate to light by controlling an exposure apparatus using the control method described above, a processing step of processing the substrate having undergone the exposure step, and a manufacturing step of manufacturing an article from the substrate having undergone the processing step. The exposure step may be understood as a step of forming a latent image pattern on a photoresist applied on a substrate. The processing step may be understood as a step of developing the substrate (photoresist) formed on the latent image pattern. This manufacturing method further includes other known steps (oxidation, deposition, vapor deposition, doping, planarization, etching, resist removal, dicing, bonding, packaging, and the like). The method of manufacturing the article according to this embodiment is advantageous in at least one of the performance, the quality, the productivity, and the production cost of the article, as compared to a conventional method.

### OTHER EMBODIMENTS

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-107227 filed on Jun. 29, 2023, which is hereby incorporated by reference herein in its entirety.

What is claimed is:

1. An exposure apparatus for exposing a substrate through a projection optical system, the apparatus comprising:
a stage configured to move while holding the substrate;
an image capturing device configured to capture an image of a mark on the substrate without going through the projection optical system;
a measurement device configured to measure a position of the stage; and
a controller configured to control alignment of the substrate based on a position of the mark and interval information, the position of the mark being obtained by using the image capturing device and the measurement device, and the interval information indicating an interval between an optical axis of the image capturing device and an optical axis of the projection optical system,
wherein the controller is configured to:
at a first timing at which the interval information is generated, cause the measurement device to measure, as a first position, a position of the stage in a predetermined state in which a reference mark on the stage is arranged within a visual field of the image capturing device; and
at a second timing after the first timing, cause the measurement device to measure, as a second position, a position of the stage in the predetermined state, and correct the interval information based on a difference between the first position and the second position.

2. The apparatus according to claim 1, wherein
the measurement device is configured to measure a position of a reference portion of the stage,
a distance between the reference portion and the reference mark on the stage changes due to a temperature of the stage, and
the controller is configured to obtain a distance difference which is a difference in the distance between the first timing and the second timing, based on a temperature difference which is a difference between a temperature of the stage at the first timing and a temperature of the stage at the second timing, and further correct the interval information by the obtained distance difference.

3. The apparatus according to claim 2, wherein if “OAS(O)” represents the first position, “OAS(t)” represents the second position, and “ΔWS” represents the difference in the distance, the controller is configured to calculates a correction value ΔBL for correcting the interval information by
$$Δ BL = OAS ( 0 ) - \{ OAS ( t ) - Δ WS \} .$$

4. The apparatus according to claim 2, further comprising a temperature detector configured to detect a temperature of the stage,
wherein the controller is configured to obtain the temperature difference based on detection results obtained by the temperature detector at the first timing and the second timing.

5. The apparatus according to claim 2, wherein the controller configured to obtain in advance a coefficient for converting a change amount of temperature of the stage into a change amount of the distance and obtains the distance difference based on the temperature difference and the coefficient.

6. The apparatus according to claim 2, further comprising a second image capturing device configured to capture an image of a mark on the substrate through the projection optical system,
wherein the controller is configured to generate, at the first timing, the interval information based on a difference between a measurement result obtained by the measurement device in a state in which a second reference mark on the stage is arranged within the visual field of the image capturing device and a measurement result obtained by the measurement device in a state in which the second reference mark is arranged within a visual field of the second image capturing device, and
on the stage, the reference mark is nearer to the reference portion than the second reference mark.

7. The apparatus according to claim 6, wherein the reference mark is nearer to the image capturing device than the second reference mark in a state in which the stage is arranged in a substrate loading place, and
the substrate loading place is a place in which the stage is arranged when the substrate is loaded onto the stage.

8. The apparatus according to claim 2, wherein the measurement device includes an interferometer, and
the reference portion is a portion of the stage which is provided with a reflecting surface that reflects light from the interferometer.

9. The apparatus according to claim 2, wherein the measurement device includes an encoder, and
the reference portion is a portion of the stage which is provided with a scale of the encoder.

10. The apparatus according to claim 1, wherein the predetermined state is a state in which the reference mark is arranged at a predetermined position within the visual field of the image capturing device.

11. The apparatus according to claim 10, wherein the predetermined position is a visual field center of the image capturing device.

12. A control method for an exposure apparatus that includes a projection optical system, a stage configured to move while holding a substrate, an image capturing device configured to capture an image of a mark on the substrate without going through the projection optical system, and a measurement device configured to measure a position of the stage, and performs alignment of the substrate based on a position of the mark and interval information, wherein the position of the mark is obtained by using the image capturing device and the measurement device, and the interval information indicates an interval between an optical axis of the image capturing device and an optical axis of the projection optical system, the method comprising:
at a first timing at which the interval information is generated, causing the measurement device to measure, as a first position, a position of the stage in a predetermined state in which a reference mark on the stage is arranged within a visual field of the image capturing device; and
at a second timing after the first timing, causing the measurement device to measure, as a second position, a position of the stage in the predetermined state, and correcting the interval information based on a difference between the first position and the second position.

13. A method of manufacturing an article, the method comprising:
exposing a substrate by controlling an exposure apparatus using a control method defined in claim 12;
processing the substrate having undergone the exposing; and
manufacturing an article from the substrate having undergone the processing.
